(19) United States
(12) Patent Application Publication
(10) Pub. No.: US 2007/0147012 A1
(43) Pub. Date: Jun. 28, 2007

(54) Circuit board

(75) Inventor: Naoya Tanaka, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto (JP)

(21) Appl. No.: 10/576,054

(22) PCT Filed: Oct. 18, 2004
(86) PCT No.: PCT/JP04/15355

§ 371 Date: Apr. 18, 2006

(30) Foreign Application Priority Data
Oct. 21, 2003 (JP) 2003-360173

(51) Int. Cl. H05K 5/00

(52) U.S. Cl. 361/752

(57) ABSTRACT

A circuit board (X4) according to the present invention includes a wiring board (1) having a width and electronic components (2). The wiring board (1) includes a first portion (1A), which has a relatively large cross section extending across the wiring board (1) in the direction of the width (W), and a second portion (1B), which has a relatively small cross section extending across the wiring board (1) in the direction of the width (W). The electronic components (2) are mounted onto the first portions (1A) of the wiring board (1). Preferably, the wiring board (1) includes a recess (1a, 1d, 1e) for partially reducing the width of the wiring board (1). Preferably, the wiring board (1) includes a hole (1b) penetrating the wiring board (1). Preferably, the wiring board (1) includes a groove (1f) for partially reducing the thickness of the wiring board (1).

### TECHNICAL FIELD

The present invention relates to a circuit board comprising a wiring board and electronic components mounted thereon.

### BACKGROUND ART

For example, a battery pack used for a mobile phone comprises a circuit board including a protection circuit formed thereon to prevent a rechargeable battery, which is installed inside of the battery pack, from overcharging or over-discharging. Such a circuit board for a battery pack is disclosed in Patent Document 1 below, for example.

Patent Document 1: JP-A-2002-135000

FIG. 5 illustrates a circuit board X5, which is an example of conventional circuit boards used for battery packs. The circuit board X5 includes a wiring board 51 as a supporting material, a plurality of electronic components 52 mounted on the wiring board 51 so as to constitute the predetermined protection circuit, and a pair of metal plates 53 for connection with the rechargeable battery.

The wiring board 51 is made of insulating material such as glass epoxy resin and in the shape of a rectangular corresponding to the shape of the battery pack which accommodates the circuit board X5. The electronic components 52 are soldered to the wiring board 51 by reflow soldering, and electrically connected with the pair of metal plates 53 via wiring patterns (not illustrated) formed on the wiring board 51.

In the process to build the circuit board X5 into the battery pack or similar processes, a bending force F is applied to the circuit board X5 to bend a component side of the circuit board X5, thereby producing a bending deformation in the circuit board X5 or the wiring board 51. In this case, the circuit board X5 suffers deformations in various places, thereby causing generation of stresses such as a flexure stress. When a large stress is generated at a soldered portion where an electronic component 52 is bound up to the wiring board 51, for example, a total or partial disconnection may occur between the soldered portion and the wiring board 51 or the electronic component 52 (i.e. the electronic component 52 may be detached from the wiring board 51). Such detachment of electronic components from the wiring board should be prevented so as to secure the function of the circuit board X5 as a protection circuit.

### DISCLOSURE OF THE INVENTION

The present invention has been proposed under the circumstances described above. Accordingly, it is an object of the present invention to provide a circuit board which can properly prevent detachment of electronic components from the wiring board even in the case that a bending force is applied to the wiring board in a manner such that the component side thereof is bent.

According to the first aspect of the present invention, there is provided a circuit board comprising: a wiring board having a width; and an electronic component. The wiring board comprises a first portion and a second portion. The first portion has a relatively large cross section extending across the wiring board in a direction of the width, while the second portion has a relatively small cross section extending across the wiring board in the direction of the width. The electronic component is mounted onto the first portion of the wiring board.

In this circuit board, the second portion of the wiring board has a smaller section modulus against a bending moment than the first portion has. When a bending force is applied to the circuit board in a manner such that a component side of the wiring board is bent, thereby generating a bending deformation in the circuit board or the wiring board, the second portion suffers a larger deformation than the first portion suffers, whereas the first portion faces a suppressed deformation. Accordingly, a flexure stress due to the bending force generate concentratedly on the second portion in the wiring board, whereby the circuit board suffers suppressed stresses such as flexure stresses generated in the first portion of the wiring board, the electronic components fixed to the first portion of the wiring board, and the soldered portions where the electronic components are bound up to the first portion of the wiring board. In this way, in the case that a bending force is applied to the present circuit board, it is possible to concentrate the stress generation on the second portion (to which no electronic components is fixed) of the wiring board and to suppress the stress generation in the first portion (to which electronic components are fixed) of the wiring board. Such suppression of the stress generation in the first portion properly inhibits detachment of electronic components from the first portion of the wiring board.

As described above, it is possible to properly inhibit detachment of electronic components from the wiring board notwithstanding application of a bending force to bend a component side of the wiring board of the present circuit board. Accordingly, the present circuit board allows electronic components mounted on the circuit board to function properly, permitting desired function as a protection circuit.

According to the second aspect of the present invention, there is provided a circuit board comprising: a wiring board having a width; a first electronic component; and a second electronic component. The wiring board includes two first portions and a second portion, where each of the two first portions has a relatively large cross section extending across the wiring board in a direction of the width, while the second portion, disposed between the two first portions, has a relatively small cross section extending across the wiring board in the direction of the width. The first electronic component is mounted on one of the two first portions of the wiring board, while the second electronic component is mounted on the other of the two first portions of the wiring board.

In this circuit board, due to the same reason as described above with regard to the circuit board according to the first aspect, it is possible to properly inhibit detachment of electronic components from the wiring board.

According to the third aspect of the present invention, there is provided a circuit board comprising: a wiring board having a width; and a plurality of electronic components. The wiring board comprises a plurality of first portions and a plurality of second portions, where each of the first portions has a relatively large cross section extending across the wiring board in a direction of the width, while each of the second portions has a relatively small cross section extending across the wiring board in the direction of the width. Each of the electronic components is mounted on one of the first portions of the wiring board.

In this circuit board, due to the same reason as described above with regard to the circuit board according to the first aspect, it is possible to properly inhibit detachment of electronic components from the wiring board. In addition, in this circuit board, the more the wiring board includes the second portions, the less generation of deformation or stress each of the second portion tends to suffer, and the much tolerance the entirety of the wiring board tends to show against bending deformation.

Preferably, the wiring board may be provided with a recess reducing partially the width of the wiring board. With such a configuration, there is properly provided the second portion having a relatively small cross section cutting across the wiring board in the direction of the width. Further, the recess may be also used for positioning at the step where the circuit board is installed to a prescribed location.

Preferably, the wiring board may be provided with a hole penetrating the wiring board. With such a configuration, the wiring board properly includes the second portion.

Preferably, the wiring board may be provided with a groove partially reducing a thickness of the wiring board. More preferably, the electronic component may be mounted on one surface of the wiring board whereas the groove is formed on the other surface opposite to the above-mentioned surface. With such a configuration, the wiring board can secure surface area large enough to form wiring patterns which need be prepared on a surface of the wiring board.

### BRIEF DESCRIPTION OF THE DRAWINGS

FIG. 1 is a perspective view illustrating a circuit board according to the first embodiment of the present invention.

FIG. 2 is a perspective view illustrating a circuit board according to the second embodiment of the present invention.

FIG. 3 is a perspective view illustrating a circuit board according to the third embodiment of the present invention.

FIG. 4 is a perspective view illustrating a circuit board according to the fourth embodiment of the present invention.

FIG. 5 is a perspective view illustrating an example of a circuit board according to a conventional art.

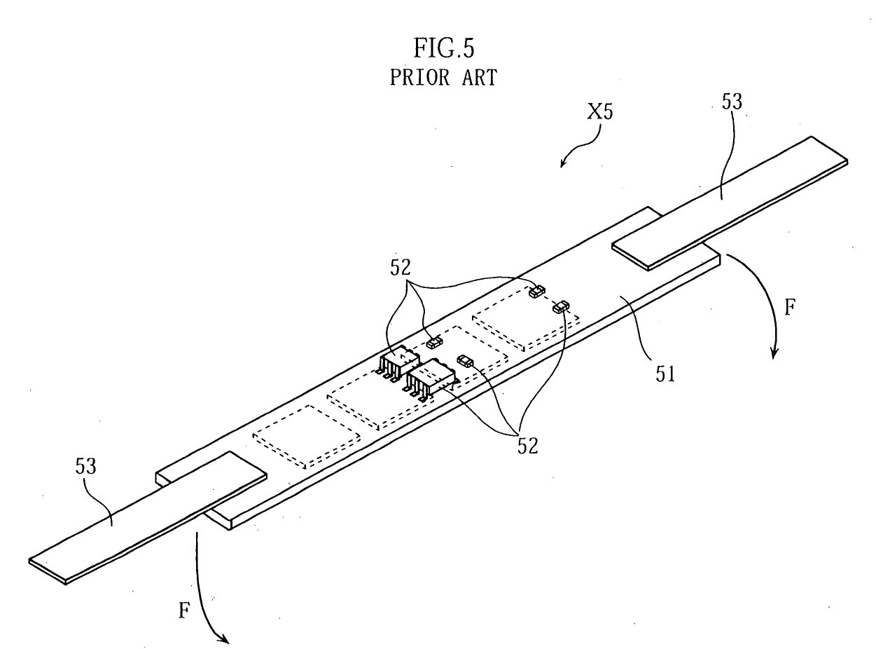

### BEST MODE FOR CARRYING OUT THE INVENTION

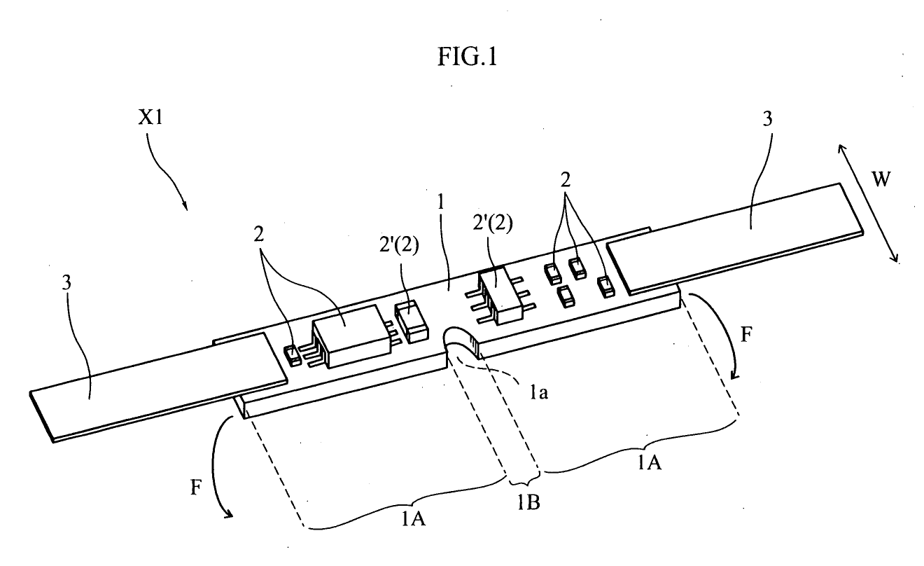

FIG. 1 illustrates a circuit board X1 according to the first embodiment of the present invention. The circuit board X1 is to be installed inside of a battery pack and serves a function as a protection circuit to prevent over-discharging or overcharging of a rechargeable battery, which is installed inside of the battery pack. The circuit board includes a wiring board 1, a plurality of electronic components 2, and a pair of metal plates 3.

The wiring board 1 is made of insulating resin such as glass epoxy resin, takes the form of a substantial rectangular suitable for a slim battery pack which allows downsizing of a mobile phone, and includes first portions 1A and a second portion 1B. The second portion 1B has a smaller cross-section, which cuts across the wiring board 1 in the direction of the width W, than the first portions 1A have, and thereby can be deformed easily through bending. The longitudinally central region of the wiring board 1 has a recess 1a which partly reduces the width of the wiring board 1, and the recess 1a segments the wiring board 1 into the first portions 1A and the second portion 1B. In this embodiment, the recess 1a has a half-round outline. The recess 1a can be easily provided in the manufacturing process of the wiring board 1, such as the step of forming the outer shape of the wiring board 1. The recess 1a may be also used for positioning in the step where the circuit board X1 is installed into the battery pack as described below.

The electronic components 2 serve to constitute a protection circuit of the battery pack into which the circuit board X1 is installed, and is mounted and soldered onto the first portions 1A of the wiring board 1. Among the electronic components 2, two electronic components 2′, which are close to the second portion 1B (i.e. the portion which can be deformed easily through bending), are mounted on the wiring board 1 in a manner such that each of the two electronic components 2′ is spaced apart from the second portion 1B by an equal distance.

The pair of metal plates 3 serves as terminals to connect the rechargeable battery in the battery pack with the circuit board X1, and is made of e.g. nickel or a nickel alloy. In addition, the pair of metal plates 3 is electrically connected with the electronic components 2 via wiring patterns (not illustrated) formed on a surface of the wiring board 1.

With the configuration described above, manufacturing process of the battery pack may include e.g. the step of folding or bending some predetermined portions of the pair of metal plates 3 before installation of the circuit board X1 into the battery pack. In such a way to install the circuit board X1 into the battery pack, a bending force F may be applied to the wiring board X1 in a manner such that the component side of the wiring board 1 is bent, whereby bending deformation may be generated in the circuit board X1 or the wiring board 1.

In the circuit board X1, the second portion 1B of the wiring board 1 has a smaller section modulus against a bending moment than the first portions 1A have. When a bending force F is applied to the circuit board X1 in a manner such that the component side of the wiring board 1 is bent, thereby generating bending deformation in the circuit board X1 or the wiring board 1, the second portion 1B suffers larger deformation than the first portions 1A suffer, whereas the first portions 1A face suppressed deformation. As a result, a flexure stress due to the bending force F is generated concentratedly on the second portion 1B in the wiring board 1, whereby the circuit board X1 suffers suppressed stresses such as flexure stresses generated in the first portions 1A of the wiring board 1, the electronic components 2 fixed thereto, and the soldered portions where the electronic components are bound up to the wiring board. In this way, by using the circuit board X1, even in the case that a bending force F is applied to the circuit board X1, it is possible to concentrate the stress generation on the second portion 1B (to which no electronic components 2 is fixed) of the wiring board 1 and to suppress stress generation in the first portions 1A (to which electronic components 2 are fixed) of the wiring board 1. Such suppression of stress generation in the first portions 1A properly inhibits detachment of the electronic components 2 from the first portions 1A of the wiring board 1.

As described above, it is possible to properly inhibit detachment of the electronic components 2 from the wiring board 1 notwithstanding application of a bending force F to bend the component side of the wiring board 1 of the circuit board X1. Accordingly, the circuit board X1 allows the electronic components 2 mounted on the circuit board X1 to function properly, permitting a desired function as a protection circuit.

Moreover, as mentioned above, the two electronic components 2′ located close to the second portion 1B are mounted on the wiring board 1 of the circuit board X1 in a manner such that each of the two electronic components 2′ is spaced apart from the second portion 1B by an equal distance. With such a symmetric configuration, it can be properly prevented that, in the wiring board 1, the deformation generated where one of the electronic components 2′ is fixed becomes inappropriately larger than the deformation generated where the other one of the electronic components 2′. As a result, this kind of symmetric configuration is suitable to inhibit detachment of, in particular, an electronic component 2′ which is close to the second portion 1B.

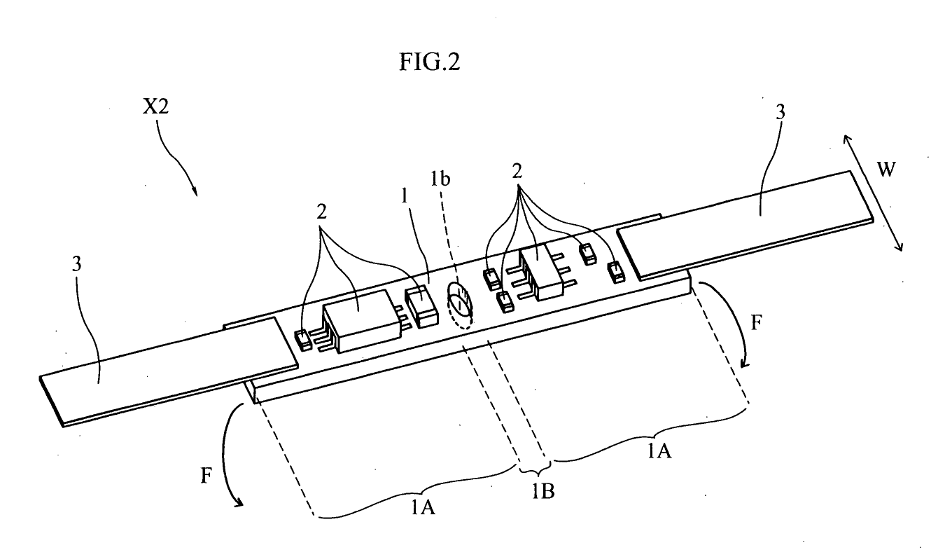

FIG. 2 illustrates a circuit board X2 according to the second embodiment of the present invention. The circuit board X2 comprises a wiring board 1, a plurality of electronic components 2, and a pair of metal plates 3 similarly to the above-described circuit board X1, and also comprises a hole 1b instead of a recess 1a differently.

This embodiment features the hole 1a which is formed at the wiring board 1 to penetrate the wiring board 1, whereby the wiring board 1 is segmented into first portions 1A and a second portion 1B (i.e. the portion which can be deformed easily through bending), which has a smaller cross section cutting across the wiring board 1 in the direction of the width W than the first portions 1A have. In this embodiment, the hole 1b takes the shape of ellipse extending in the direction of the width W. Instead of the single hole 1b, the wiring board 1 may employ a plurality of holes aligning in the direction of width W.

The other factors in configuration of the wiring board 1, factors in configuration of the electronic components 2, and factors in configuration of the pair of metal plates 3 are the same as described above with regard to the circuit board X1.

Similarly to as described above with regard to the circuit board X1, in the case that a bending force F is applied to the circuit board X2, it is possible to concentrate stress generation on the second portion 1B (to which no electronic components 2 is fixed) of the wiring board 1 and to suppress stress generation in the first portions 1A (to which electronic components 2 are fixed) of the wiring board 1. Accordingly, the circuit board X2 is prevented properly from suffering detachment of the electronic components 2 out of the first portions 1A of the wiring board 1 as well.

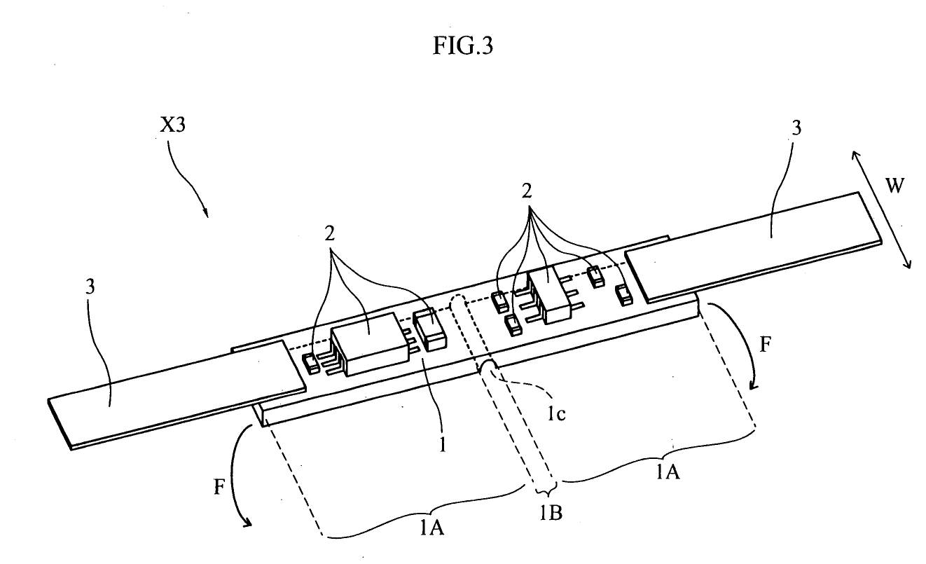

FIG. 3 illustrates a circuit board X3 according to the third embodiment of the present invention. The circuit board X3 comprises a wiring board 1, a plurality of electronic components 2, and a pair of metal plates 3 similarly to the above-described circuit board X1, and also comprises a groove 1c instead of a recess 1a differently.

The groove 1c featured by this embodiment is formed at, in the figure, the lower surface (to which no electronic components 2 is fixed) of the wiring board 1 so as to reduce partially a thickness of the wiring board 1. The groove 1c segments the wiring board 1 into first portions 1A and a second portion 1B (i.e. the portion which can be deformed easily through bending), which has a smaller cross section cutting across the wiring board 1 in the direction of the width W than the first portions 1A have. The electronic components 2 are not soldered to the above-described second portion, but to the first portions.

The other factors in configuration of the wiring board 1, the other factors in configuration of the electronic components 2, and factors in configuration of the pair of metal plates 3 are the same as described above with regard to the circuit board X1.

Similarly to as described above with regard to the circuit board X1, in the case that a bending force F is applied to the circuit board X3, it is possible to concentrate stress generation on the second portion 1B (to which no electronic components 2 is fixed) of the wiring board 1 and to suppress stress generation in the first portions 1A (to which electronic components 2 are fixed) of the wiring board 1. Accordingly, the circuit board X3 is prevented from suffering detachment of the electronic components 2 out of the first portions 1A of the wiring board 1 as well.

In addition, in formation of wiring patterns (not illustrated) which connect electrically with the electronic components 2, the circuit board X3 allows securement of enough area to form wiring patterns on the entire surface of the wiring board 1 and thus setting a pitch of the wiring patterns large adequately.

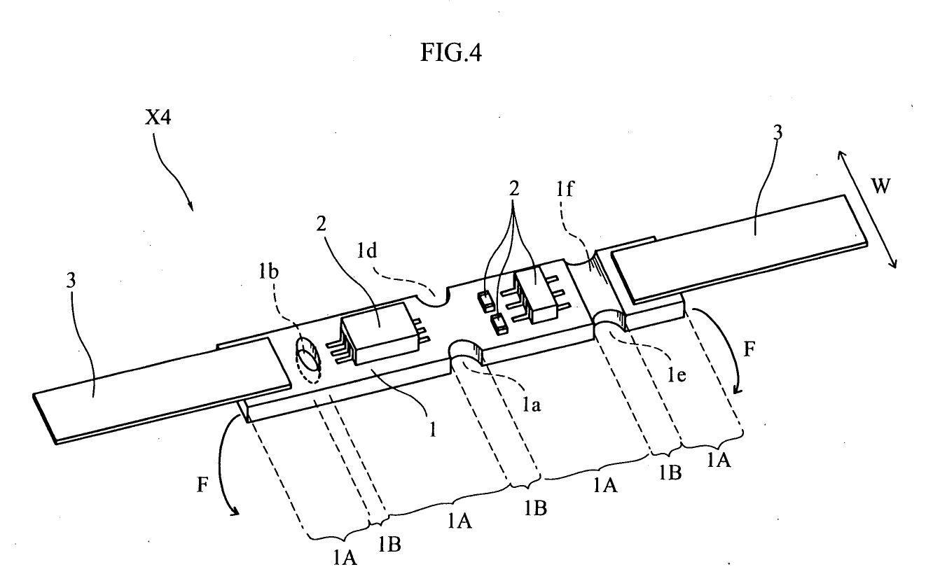

FIG. 4 illustrates a circuit board X4 according to the fourth embodiment of the present invention. The circuit board X4 comprises a wiring board 1, a plurality of electronic components 2, and a pair of metal plates 3 similarly to the above-described circuit board X1, and also comprises a recess 1d, 1e, a hole 1b, and a groove if instead of a recess 1a differently.

In this embodiment, the wiring board 1 includes four first portions 1A and three second portions 1B (i.e. the portions which can be deformed easily through bending), each of which has a smaller cross section cutting across the wiring board 1 in the direction of the width W than the first portions 1A have.

The second portion 1B on the left side in the figure is produced by formation of the hole 1b which penetrates the wiring board 1. The present invention may employ a plurality of holes aligning in the direction of width W instead of the single hole 1b. The second portion 1B in the center in the figure is produced by formation of the pair of recesses 1a, 1d, reducing partially the width of the wiring board 1. The second portion 1B in the right side in the figure is produced by formation of the recess 1e, which is formed at an edge of the wiring board 1 so as to reduce partially the width of the wiring board 1, and also by formation of a groove 1f, which is formed on the upper surface of the wiring board in the figure so as to reduce partially the thickness of the wiring board 1. The electronic components 2 are not soldered to the above-described second portions, but to the first portions.

The other factors in configuration of the wiring board 1, the other factors in configuration of the electronic components 2, and factors in configuration of the pair of metal plates 3 are the same as described above with regard to the circuit board X1.

Similarly to as described above with regard to the circuit board X1, in the case that a bending force F is applied to the circuit board X4, it is possible to concentrate stress generation on the second portions 1B (to which no electronic components 2 is fixed) of the wiring board 1 and to suppress stress generation in the first portions 1A (to which electronic components 2 are fixed) of the wiring board 1. Accordingly, the circuit board X3 is prevented from suffering detachment of the electronic components 2 out of the first portions 1A of the wiring board 1 as well.

In addition, because the circuit board X4 includes the second portions 1B in the wiring board 1, stresses are diffracted to the second portions 1B when a bending force F is applied. Accordingly, with use of the circuit board X4, it is possible to suppress generation of deformation or stress in a single second portion 1B, or to accept larger bending deformation over the entirety of the wiring board 1, whereby the circuit board X4 is preferable to the circuit boards X1-X3, each of which includes only single second portion 1B in the wiring board 1. The circuit board X1 is suitable to suppress deformation or a stress generated in a single second portion 1B, and tends to show larger endurance.

The circuit board according to the present invention is not limited to application to a protection circuit for a battery pack. In other words, the electronic components may constitute a circuit other than a protection circuit with no limitation on kind or function of the circuit.

Further, the present invention is suitable for, but is not limited to, application to a circuit board on which a plurality of electronic components is mounted. The present invention may be applied to a circuit board on which a single electronic component is mounted.

Moreover, the present invention may employ a second portion produced by formation of proper combination including a recess, a hole, or a groove, as exemplified by the second portions in the center and on the right side in the FIG. 4.

1. A circuit board comprising:
a wiring board having a width; and an electronic component;
wherein the wiring board comprises a first portion and a second portion, the first portion having a relatively large cross section extending across the wiring board in a direction of the width, the second portion having a relatively small cross section extending across the wiring board in the direction of the width,
wherein the electronic component is mounted onto the first portion of the wiring board.

2. The circuit board according to claim 1, wherein the wiring board is provided with a recess for partially reducing the width of the wiring board.

3. The circuit board according to claim 1, wherein the wiring board is provided with a hole penetrating the wiring board.

4. The circuit board according to claim 1, wherein the wiring board is provided with a groove for partially reducing a thickness of the wiring board.

5. The circuit board according to claim 4, wherein the groove is formed in a surface of the wiring board that is opposite to another surface upon which the electronic component is mounted.

6. A circuit board comprising:
a wiring board having a width; a first electronic component; and a second electronic component;
wherein the wiring board includes two first portions and a second portion, each first portion having a relatively large cross section extending across the wiring board in a direction of the width, the second portion intervening between the two first portions and having a relatively small cross section extending across the wiring board in the direction of the width,
wherein the first electronic component is mounted on one of the two first portions of the wiring board,
wherein the second electronic component is mounted on the other of the two first portions of the wiring board.

7. A circuit board comprising:
a wiring board having a width; and a plurality of electronic components;
wherein the wiring board comprises a plurality of first portions and a plurality of second portions, each first portion having a relatively large cross section extending across the wiring board in a direction of the width, each second portion having a relatively small cross section extending across the wiring board in the direction of the width,
wherein each of the electronic components is mounted on one of the first portions of the wiring board.
